(19) United States
(12) Patent Application Publication
(10) Pub. No.: US 2023/0163748 A1
(43) Pub. Date: May 25, 2023

(54) SURFACE ACOUSTIC WAVE DEVICES WITH RAISED FRAME STRUCTURE

(71) Applicant: Skyworks Solutions, Inc., Irvine, CA (US)

(72) Inventors: Rei Goto, Osaka-Shi (JP); Hironori Fukuhara, Ibaraki-Shi (JP)

(21) Appl. No.: 17/991,729

(22) Filed: Nov. 21, 2022

Related U.S. Application Data
(60) Provisional application No. 63/282,432, filed on Nov. 23, 2021.

(51) Int. Cl. H03H 9/02; H03H 9/145

(52) U.S. Cl. CPC H03H 9/02992; H03H 9/14541; H03H 9/02574

(57) ABSTRACT

An acoustic wave device can include a substrate, a piezoelectric layer, a first electrode that includes a first bus bar and a first plurality of fingers extending from the first bus bar, and a second electrode that includes a second bus bar and a second plurality of fingers extending from the second bus bar. The second plurality of fingers can be interdigitated with the first plurality of fingers. The acoustic wave device can include a raised frame structure. The raised frame structure can be configured to suppress a transverse mode. The fingers can have widths that are greater than the distances between the fingers. The acoustic wave device can include a bus bar that includes a main section and a secondary section that are electrically connected by gap lines, which can have smaller width than the fingers. The acoustic wave device can include dummy fingers.

### CROSS REFERENCE TO PRIORITY APPLICATIONS

This application claims the benefit of priority U.S. Provisional Patent Application No. 63/282,432, filed Nov. 23, 2021 and titled “SURFACE ACOUSTIC WAVE DEVICES WITH RAISED FRAME STRUCTURE,” the contents of which are hereby incorporated by reference in their entirety. Any and all applications for which a foreign or domestic priority claim is identified in the Application Data Sheet as filed with the present application are hereby incorporated by reference under 37 CFR 1.57.

### BACKGROUND

### Technical Field

Embodiments of this disclosure relate to acoustic wave devices, such as surface acoustic wave devices, and more particularly to structures for suppressing a transverse mode in acoustic wave devices.

### Description of Related Technology

Acoustic wave filters can be implemented in radio frequency electronic systems. For instance, filters in a radio frequency front end of a mobile phone can include acoustic wave filters. An acoustic wave filter can include a plurality of acoustic resonators arranged to filter a radio frequency signal. Example acoustic wave filters include surface acoustic wave (SAW) filters and bulk acoustic wave (BAW) filters. SAW filters can include SAW resonators. A SAW resonator of a surface acoustic wave filter typically includes an interdigital transducer electrode on a piezoelectric substrate. A surface acoustic wave resonator is arranged to generate a surface acoustic wave.

Although various SAW devices exist, there remains a need for improved SAW devices and filters, such as with improved transverse mode suppression.

### SUMMARY OF CERTAIN INVENTIVE ASPECTS

Without limiting the scope of the claims, certain example embodiments are summarized below for illustrative purposes. Embodiments may include several novel features, no single one of which is solely responsible for its desirable attributes or which is essential to the embodiments.

In accordance with one aspect of the disclosure, an acoustic wave device can include a substrate, a piezoelectric layer, and an interdigital transducer electrode, which can include a plurality of fingers separated by gaps. The piezoelectric layer can be disposed between the substrate and the interdigital transducer electrode. The acoustic wave device can include a raised frame structure. The interdigital transducer can be disposed between the piezoelectric layer and the raised frame structure.

The acoustic wave device can include a passivation layer disposed between the raised frame layer and the interdigital transducer electrode. The acoustic wave device can include a passivation layer, and the raised frame layer can be between the passivation layer and the interdigital transducer electrode. The raised frame structure can include silicon dioxide and/or the passivation layer can include silicon nitride. The gaps between the fingers can include an insulating material. The raised frame structure can be configured to suppress a transverse mode. The acoustic wave device can include an active region where the plurality of fingers overlap, a first raised frame structure extending along a first side of the active region, and a second raised frame structure extending along a second side of the active region opposite the first side. A width of an inner region between the first raised frame structure and the second raised frame structure can be larger than a combined width of the first raised frame structure and the second raised frame structure. The fingers can occupy a majority of the active area, and the gaps between fingers can occupy a minority of the active area. The fingers can occupy a first area of the active region, the gaps between the fingers can occupy a second area of the active region, and the first area can be larger than the second area. A width of one of the fingers divided by a combined width of the finger and one of the gaps can provide a duty function that is between about 0.5 and about 0.75. The raised frame structure can have a height that is between about 1% and about 8% of a combined width of one of the fingers and one of the gaps. The raised frame structure can have a width that is between about 80% and about 240% or about 300% of a combined width of one of the fingers and one of the gaps.

The interdigital transducer electrode can include at least one bus bar that extends in a first direction, and the fingers can extend in a second direction that is substantially perpendicular to the first direction. The interdigital transducer electrode can include a first bus bar, a second bus bar, a first plurality of fingers extending from the first bus bar towards the second bus bar, and a second plurality of fingers extending towards the first bus bar. The interdigital transducer can include a first plurality of dummy fingers extending from the first bus bar. The first plurality of dummy fingers can be shorter than the first plurality of fingers. The first plurality of dummy fingers can be aligned with the second plurality of fingers. The interdigital electrode can have a second plurality of dummy fingers extending from the second bus bar. The second plurality of dummy fingers can be shorter than the second plurality of fingers. The second plurality of dummy fingers can be aligned with the first plurality of fingers. The first bus bar can include a main portion and a secondary portion that is inward of the main portion and spaced apart from the main portion. The second bus bar can include a main portion and a secondary portion that is inward of the main portion and spaced apart from the main portion. A plurality of first gap lines can extend from the main portion to the secondary portion of the first bus bar. The first gap lines can have widths that are smaller than widths of the first plurality of fingers. A plurality of second gap lines can extend from the main portion to the secondary portion of the second bus bar. The second gap lines can have widths that are smaller than widths of the second plurality of fingers. The interdigital transducer electrode can include a main bus bar portion and a secondary bus bar portion that is spaced apart from the main bus bar portion. A first set of the plurality of fingers can extend from the secondary bus bar portion. At least one gap line can extend between and electrically interconnect the main bus bar portion and the secondary bus bar portion. The gap line can have a width that is smaller than a width of one of the plurality of fingers. The interdigital transducer electrode can include a plurality of dummy fingers that are shorter than the plurality of fingers. The fingers can include a stem portion and a head portion that is wider than the stem portion.

In accordance with one aspect of the disclosure, an acoustic wave device can include a substrate, a piezoelectric layer, a first electrode that includes a first bus bar and a first plurality of fingers extending from the first bus bar, and a second electrode that includes a second bus bar and a second plurality of fingers extending from the second bus bar. The second plurality of fingers can be interdigitated with the first plurality of fingers. The acoustic wave device can include a raised frame structure.

The raised frame structure can include a first raised frame disposed over ends of the first fingers and a second raised frame over ends of the second fingers. The acoustic wave device can include a passivation layer disposed between the raised frame structure and the first and second electrodes. The acoustic wave device can include a passivation layer disposed over the raised frame structure. The raised frame structure can include silicon dioxide and the passivation layer can include silicon nitride. The raised frame structure can be configured to suppress a transverse mode.

The acoustic wave device can include an active region where the first plurality of fingers overlap the second plurality of fingers. The raised frame structure can have a first raised frame extending along a first side of the active region, and a second raised frame extending along a second side of the active region opposite the first side. A width of an inner region between the first raised frame and the second raised frame can be larger than a combined width of the first raised frame and the second raised frame. The first plurality of fingers and the second plurality of fingers can occupy a majority of the active area. The first plurality of fingers and the second plurality of fingers can have a duty function that is greater than 0.5. A width of one of the first plurality of fingers can be larger than the space between that finger and an adjacent one of the second plurality of fingers.

A first side of one of the first plurality of fingers can be spaced away from a first side of a next one of the first plurality of fingers by a distance L. The raised frame structure can have a height that is between about 0.005 times and about 0.04 times the distance L. The raised frame structure can have a height that is between about 0.5% and 4% of the combined width of one of the first plurality of fingers, one of the second plurality of fingers, a first gap between the one of the first plurality of fingers and the one of the second plurality of fingers, and a second gap between the one of the second plurality of fingers and a next one of the first plurality of fingers. The raised frame structure having a width that is between about 0.4 times and about 1.5 times (e.g., about 1.2 times) the distance L. The raised frame structure can have a width that is between about 40% and 150% of the combined width of one of the first plurality of fingers, one of the second plurality of fingers, a first gap between the one of the first plurality of fingers and the one of the second plurality of fingers, and a second gap between the one of the second plurality of fingers and a next one of the first plurality of fingers.

The first plurality of fingers can extend substantially perpendicular to first bus bar, and/or the second plurality of fingers can extend substantially perpendicular to the second bus bar. The raised frame structure can extend substantially perpendicular to the first or second plurality of fingers. The raised frame structure can extend substantially parallel to the first or second bus bar. The first bus bar can include a main portion and a secondary portion that is inward of the main portion and spaced apart from the main portion. The second bus bar can include a main portion and a secondary portion that is inward of the main portion and spaced apart from the main portion. The first bus bar can includes a plurality of first gap lines that extend from the main portion to the secondary portion of the first bus bar. The first gap lines can have widths that are smaller than widths of the first plurality of fingers. The second bus bar can include a plurality of second gap lines that extend from the main portion to the secondary portion of the second bus bar. The second gap lines can have widths that are smaller than widths of the second plurality of fingers. A first side of one of the first plurality of fingers can be spaced away from a first side of a next one of the first plurality of fingers by a distance L, and the first gap lines can have widths between about 0.1 times the distance L and about 0.2 times the distance L.

The acoustic wave device can include a first plurality of dummy fingers extending from the first bus bar. The first plurality of dummy fingers can be shorter than the first plurality of fingers. The first plurality of dummy fingers can be aligned with the second plurality of fingers. The acoustic wave device can include a second plurality of dummy fingers extending from the second bus bar. The second plurality of dummy fingers can be shorter than the second plurality of fingers. The second plurality of dummy fingers can be aligned with the first plurality of fingers. The first plurality of dummy fingers can have lengths that are between about 0.05 time the distance L and about 0.3 times the distance L. The first plurality of dummy fingers can have widths that are between about 0.15 times the distance L and about 0.65 times the distance L. The first plurality of dummy fingers can be spaced from corresponding ones of the second plurality of fingers by gaps having distances between about 0.05 time the distance L and about 0.3 times the distance L. Each or any of the first plurality of fingers and/or each or any of the second plurality of fingers can include a stem portion and a head portion that is wider than the stem portion.

The acoustic wave device can be a surface acoustic wave (SAW) device. The acoustic wave device can be a multi-layer piezoelectric substrate (MPS) device. A filter can includes one or more of the acoustic wave devices disclosed herein. The filter can be at least one of a band pass filter, a band stop filter, a ladder filter, and a lattice filter. A filter can include one or more of the acoustic wave devices disclosed herein. The filter can form part of at least one of a diplexer, a duplexer, a multiplexer, and a switching multiplexer. A radio frequency module can include an acoustic wave die that includes at least one filter, and the at least one filter can include one or more of the acoustic wave devices disclosed herein. A radio frequency circuit element can be coupled to the acoustic wave die. The acoustic wave die and the radio frequency circuit element can be enclosed within a common module package. A wireless communication device can include an acoustic wave filter that includes one or more of the acoustic wave devices disclosed herein, an antenna operatively coupled to the acoustic wave filter, a radio frequency amplifier operatively coupled to the acoustic wave filter and configured to amplify a radio frequency signal, and a transceiver in communication with the radio frequency amplifier. The wireless communication device can include a baseband processor in communication with the transceiver. The acoustic wave filter can be included in a radio frequency front end. The wireless communication device can be a user equipment.

### BRIEF DESCRIPTION OF THE DRAWINGS

Embodiments of this disclosure will now be described, by way of non-limiting example, with reference to the accompanying drawings.

FIG. 1 is a plan view of an example of an acoustic wave device.

FIG. 2 is a cross-sectional view of an example of an acoustic wave device.

FIG. 3 is a plan view of an example of an acoustic wave device.

FIG. 4 is a cross-sectional view of an example of an acoustic wave device.

FIG. 5 is a plan view of an example of an acoustic wave device.

FIG. 6 is a cross-sectional view of an example of an acoustic wave device.

FIG. 7 is a plot of admittance for example acoustic wave devices.

FIG. 8 is a plot of admittance for example acoustic wave devices.

FIG. 9 is a plan view of an example of an acoustic wave device.

FIG. 10 is a cross-sectional view of an example of an acoustic wave device.

FIG. 11 is a cross-sectional view of an example of an acoustic wave device.

FIG. 12 is a cross-sectional view of an example of an acoustic wave device.

FIG. 13 is a plan view of an example of an acoustic wave device.

FIG. 14 is a cross-sectional view of an example of an acoustic wave device.

FIG. 15 is a plan view of an example of an acoustic wave device.

FIG. 16 is a plan view of an example of an acoustic wave device.

FIG. 17 is a plan view of an example of an acoustic wave device.

FIG. 18 is a schematic diagram of an example of an acoustic wave ladder filter.

FIG. 19 is a schematic diagram of an example of a duplexer.

FIG. 20 is a schematic diagram of an example of a multiplexer.

FIG. 21 is a schematic block diagram of a module that includes an antenna switch and duplexers that include one or more acoustic wave devices.

FIG. 22A is a schematic block diagram of a module that includes a power amplifier, a radio frequency switch, and duplexers that include one or more acoustic wave devices.

FIG. 22B is a schematic block diagram of a module that includes a low noise amplifier, a radio frequency switch, and acoustic wave filters that include one or more acoustic wave devices.

FIG. 23 is a schematic block diagram of a module that includes a power amplifier, a radio frequency switch, a duplexer that includes one or more acoustic wave devices.

FIG. 24A is a schematic block diagram of a wireless communication device that includes filters that include one or more acoustic wave devices.

FIG. 24B is a schematic block diagram of another wireless communication device that includes filters that include one or more acoustic wave devices.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic resonators, including surface acoustic wave (SAW) and multi-layer piezoelectric substrate (MPS) resonators, can be used in radio frequency (RF) filters and communications systems. In some cases, a transverse mode can degrade the performance of the acoustic wave device. The acoustic wave device can include a raised frame structure, which can be configured to suppress the transverse mode. A first raised frame can be disposed along a first side of an active region and a second raised frame can be disposed along a second side of the active region. The raised frame structure can slow the edges of the active region, which can reduce or impede propagation of transvers mode.

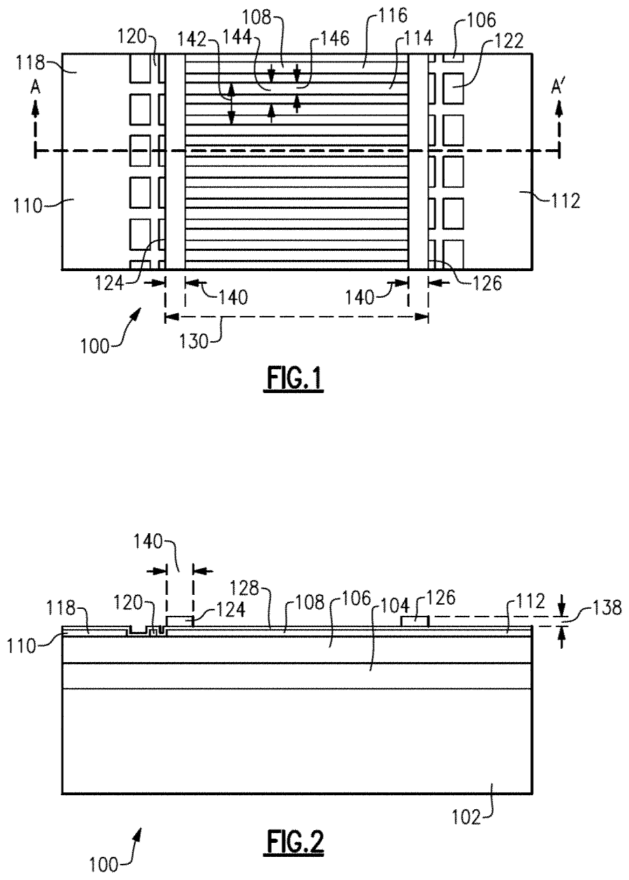

FIG. 1 is a plan view of an example embodiment of an acoustic wave device 100, which can be a surface acoustic wave (SAW) device, such as a multi-layer piezoelectric substrate (MPS) device. FIG. 2 is a cross-sectional view of the acoustic wave device 100 of FIG. 1 taken through the line from A to A′. The device 100 can include a substrate 102, a dielectric layer 104, a piezoelectric layer 106, and an interdigital transducer (IDT) electrode 108. The substrate 102 can be a support substrate, such as a substrate structure (e.g., a layer). The substrate 102 can include (e.g., be made of, consist of) a semiconductor material, such as silicon (Si) (e.g., high resistivity silicon) or gallium arsenide (GaAs), although various other suitable semiconductor materials can be used. The piezoelectric layer 106 can be a lithium based piezoelectric layer. For example, the piezoelectric layer 106 can include (e.g., be made of, consist of) lithium tantalate (LiTaO3) or lithium niobate (LiNbO3), although various other suitable piezoelectric materials can be used.

In some implementations, the substrate 102 can be formed or provided. The piezoelectric layer 106 can be formed or provided over the substrate 102 (e.g., disposed thereon, attached or adhered thereto). In some embodiments, a dielectric layer 104 can be between the substrate 102 and the piezo electric layer 106. For example, the dielectric layer 104 can be formed or provided over the substrate 102 (e.g., disposed thereon, attached or adhered thereto), and the piezoelectric layer 106 can be formed or provided over the dielectric layer 104 (e.g., disposed thereon, attached or adhered thereto). The dielectric layer 104 can include (e.g., be made of, consist of) silicon dioxide (SiO2), for example, although various other oxide materials or other insulating materials could be used.

The IDT electrode 108 can be over the piezoelectric layer 106. The IDT electrode 108 can be formed or provided over the piezoelectric layer 106 (e.g., disposed thereon, attached or adhered thereto). The IDT electrode 108 can include (e.g., be made of, consist of) aluminum (Al), molybdenum (Mo), tungsten (W), gold (Au), silver (Ag), copper (Cu), platinum (Pt), ruthenium (Ru), titanium (Ti), the like, or any suitable combination thereof, although various suitable conductive materials could be used. In some embodiments, the IDT electrode 108 can be a multi-layered IDT electrode, such as having layers of Al and Mo, having layers of Al and W, having layers of Al and Pt, or any other combination of the above-identified materials, or any other suitable conductive materials.

The IDT electrode 108 can have a first bus bar 110 (e.g., an input bus bar) and a second bus bar 112 (e.g., an output bus bar). The IDT electrode 108 can include a first plurality of fingers 114, which can extend from the first bus bar 110 towards the second bus bar 112. The IDT electrode 108 can include a second plurality of fingers 116, which can extend from the first bus bar 110 towards the second bus bar 112. The first fingers 114 can extend along gaps between the second fingers 116, and the second fingers 116 can extend along gaps between the first fingers 114. The fingers 114 and 116 can form an interdigitated structure. The piezoelectric layer 106 can be exposed at gaps between the fingers 114, 116. The gaps between finger 114, 116 can be filled with air, in some embodiments. The gaps between fingers 114, 116 can be filled with an insulating material, in some embodiments. The SAW device 100 can have an active region 130 where the first fingers 114 overlap the second fingers 116. A first electrode can include the first bus bar 110 and the first fingers 114. A second electrode can include the second bus bar 112 and the second fingers 116.

In some embodiments, the bus bar 110 and/or the bus bar 112 can include an outer or main bus bar section 118 and an inner or secondary bus bar section 120. The main bus bar section 118 can be disposed outward of the secondary bus bar section 120. The secondary bus bar section 120 can be disposed inward of the main bus bar section 118 (e.g., closer to the active region 130 or closer to the opposing fingers that extend from the opposing bus bar). The main bus bar section 118 can be wider than the secondary bus bar section 120, such as about 2 times wider, about 4 times wider, about 6 times wider, about 8 times wider, about 10 times wider, about 12 times wider, about 14 times wider, about 16 times wider, about 18 times wider, about 20 times wider, or any values or ranges between any of these numbers, although other configurations are possible. The secondary bus bar section 120 of the first bus bar 110 can interconnect the fingers 114 and/or the secondary bus bar section 120 of the second bus bar 112 can interconnect the fingers 116 of the second bus bar 114. The secondary bus bar 120 can be spaced apart from the main bus bar section 118 by a gap 122, which can be wider than the secondary bus bar section 120 and/or narrower than the main bus bar section 118. The gap 122 can be an opening through the conductive material or layer bound by the main bus bar section 118 on one side, by the secondary bus bar section 120 on another side, and by fingers 114 or 116 on the other sides.

The acoustic wave device 100 can include a raised frame structure. The raised frame structure can be disposed over the interdigitated electrode 108. A first raised frame structure 124 can extend along a first side or edge of the active area 130, and a second raised frame structure 126 can extend along a second side or edge of the active area 130. The first raised frame structure 124 can be positioned at the ends of the second fingers 116. The first raised frame structure 124 can extend substantially perpendicular to the first fingers 114 and/or the second fingers 116. The first raised frame structure 124 can extend substantially parallel to the first bus bar 110 (e.g., the main section 118 and/or secondary section 120). The first raised frame structure 124 can extend across multiple fingers 116. The first raised frame structure 124 can extend over the first fingers 114 and the second fingers 116, as well as the gaps therebetween. The second raised frame structure 126 can be positioned at the ends of the first fingers 114. The second raised frame structure 126 can extend substantially perpendicular to the first fingers 114 and/or the second fingers 116. The second raised frame structure 126 can extend substantially parallel to the second bus bar 112 (e.g., the main section 118 and/or secondary section 120). The second raised frame structure 126 can extend across multiple fingers 114. The second raised frame structure 126 can extend over the first fingers 114 and the second fingers 116, as well as the gaps therebetween. In some embodiments, the first raised frame structure 124 can be connected to the second raised frame structure 126, such as at one or more ends of the acoustic wave device 100. In other configurations, the first raised frame structure 124 can be separate from the second raised frame structure 126. The active area 130 can include an inner region between the raised frame structure(s) 124, 126. The width of the active region 130 can be divided into the inner region and the raised frame portion(s). The width of the inner region can be larger than the width (e.g., combined width) of the raised frame portion(s) of the active region 130.

The raised frame structures 124, 126 can include (e.g., be made of, consist of) a low acoustic impedance material. The low acoustic impedance material can have a lower acoustic impedance than the material of the IDT electrode 108. The low acoustic impedance material has a lower acoustic impedance than the material of the piezoelectric layer 106. As an example, the first raised frame structures 124, 126 can be a silicon dioxide (SiO2) layer. Other oxide materials can be used, and the raised frame structure 124, 126 can be an oxide raised frame structure or layer. The raised frame structure 124, 126 can be a silicon nitride (SiN) layer, a silicon carbide (SiC) layer, tantalum pentoxide (Ta2O5), or any other suitable low acoustic impedance layer. The raised frame structure 124, 126 can have a relatively low density. The density and/or acoustic impedance of the first raised frame structure 124, 126 can be lower than the density and/or acoustic impedance of the IDT electrode 108 and/or of the piezoelectric layer 106 of the device 100. The material of the raised frame structure 124, 126 can be an insulating or dielectric material.

A passivation layer 128 can be disposed between the IDT electrode 108 and the raised frame structure 124, 126. The passivation layer 128 can be disposed over the fingers 114, 116, and the piezoelectric layer at gaps between the fingers 114, 116, and/or over the bus bars 110, 112. The passivation layer 128 can be silicon nitride (SiN) or any other suitable passivation material. The passivation layer 128 can be an insulating or dielectric material. In some embodiments, a conductive material can be used for the raised frame structure 124, 126 (e.g., the same material as the IDT electrode 108), such as if an insulating layer is disposed between the IDT electrode 108 and the raised frame structure 124, 126 (e.g., a passivation layer 128 that is sufficient thick to insulate the raised frame structure 124, 126 from the IDT electrode 108). The raised frame structure 124, 126 can be formed (e.g., deposited and/or patterned) over the passivation layer 128. In FIG. 1 (as well as some other plan-view Figures), the passivation layer 128 is omitted from view to facilitate illustration of the underlying structure. In some embodiments, the passivation layer 128 can be omitted (e.g., see FIG. 11).

The raised frame structure 124, 126 can suppress spurious transverse mode(s), as compared to an acoustic wave device that does not have a raised frame structure. The raised frame structure 124, 126 can slow down acoustic wave velocity at the edge of the active region 130 as compared to the center region. By using this velocity profile the main mode field distribution in the active region can become closer to uniform (e.g., sometime referred to as piston mode operation) and transverse modes and be suppressed.

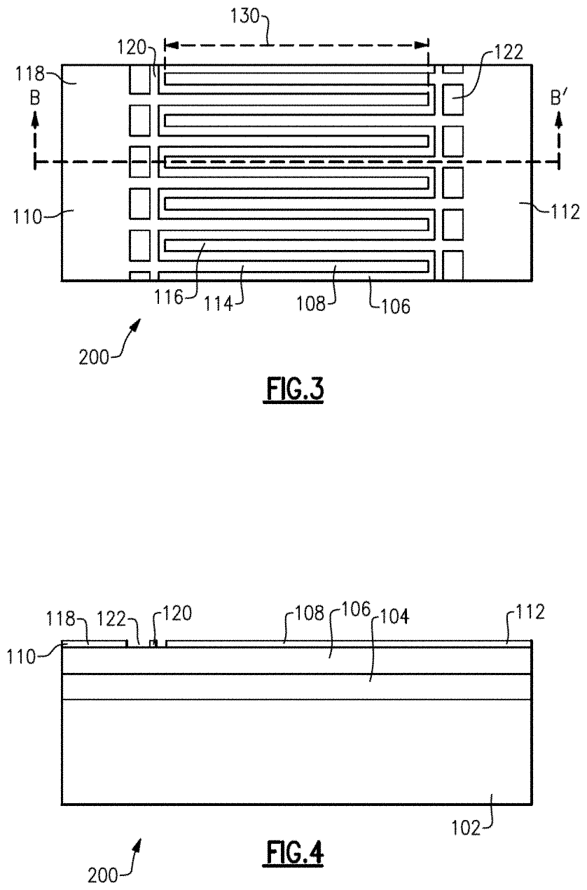

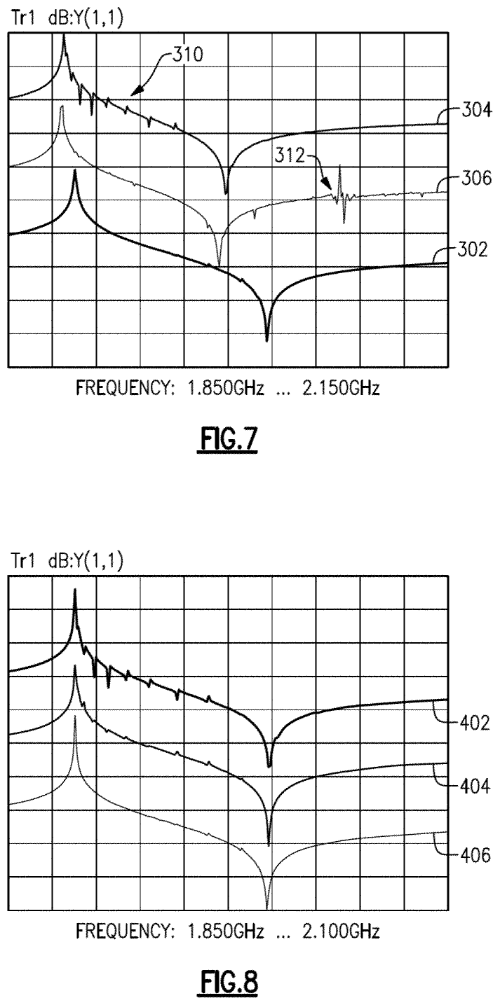

FIG. 3 shows a plan view of an example embodiment of an acoustic wave device 200, which can be similar to the acoustic wave device 100 of FIGS. 1 and 2, except that the device 200 does not include the raised frame structure 124, 126. FIG. 4 is a cross-sectional view of the acoustic wave device 200 of FIG. 3 taken through the line from B to B′. FIG. 7 shows a graph that compares the admittance for an acoustic wave device 100 that has a raised frame structure 124, 126 (e.g., according to FIGS. 1 and 2), which is represented by line 302, to the admittance for an acoustic wave device 200 that does not have the raised frame structure (e.g., as shown in FIGS. 3 and 4), which is represented by line 304. The lines 302, 304, and 306 of FIG. 7 are shown offset vertically from each other for easy of illustration and comparison. For the device 200 with no raised frame, the transverse mode can produce fluctuations at frequencies between the resonant and anti-resonant frequencies (e.g., indicated by 310). The device 100 that has the raised frame can produce a smother response between the resonant and anti-resonant frequencies, such as by suppression of transverse mode.

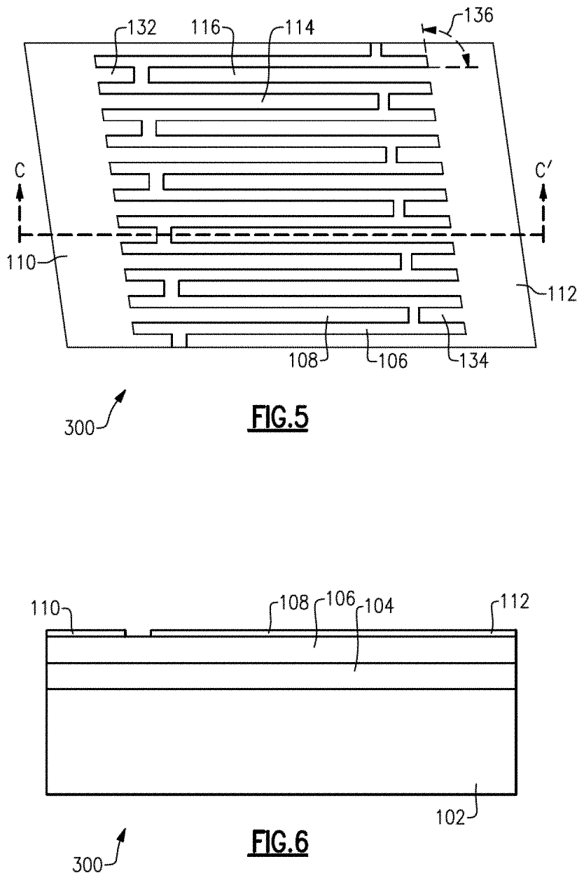

FIG. 5 shows a plan view of another example embodiment of an acoustic wave device 300, such as a SAW or MPS device. FIG. 6 is a cross-sectional view of the acoustic wave device 300 of FIG. 5 taken through the line from C to C′. The device 300 can be similar to the embodiments disclosed herein, except as discussed herein. The device 300 can include a substrate 102, dielectric layer 104, piezoelectric layer 106, and IDT electrode 108. The IDT electrode 108 can have interdigitated first and second fingers 114, 116. The IDT electrode 108 can include first dummy fingers 132, which can extend from the first bus bar 110 towards the fingers 116 or second bus bar 112. The first set of dummy fingers 132 can be positioned between corresponding first fingers 114. The first dummy fingers 132 can be shorter than the first fingers 114. The first dummy fingers 132 can be aligned with the opposing second fingers 116. The IDT electrode 108 can include second dummy fingers 134, which can extend from the second bus bar 112 towards the fingers 114 or first bus bar 112. The second set of dummy fingers 134 can be positioned between corresponding second fingers 116. The second dummy fingers 134 can be shorter than the second fingers 116. The second dummy fingers 134 can be aligned with the opposing first fingers 116. In some cases, the dummy fingers 134 can be omitted.

The device 300 can have a slanted IDT 108. The fingers 114, 116, 132, and/or 134 can extend along a first direction, and the first bus bar 110 and/or the second bus bar 112 can extend along a second direction. An angle 136 between the first direction and the second direction can be non-orthogonal. The angle 136 can be about 87 degrees, about 85 degrees, about 80 degrees, about 75 degrees, about 70 degrees, about 60 degrees, or less, or the angle 136 can be about 93 degrees, about 95 degrees, about 100 degrees, about 105 degrees, about 110 degrees, about 120 degrees, or any values between any of these angles, or any ranges between any of these angles, although other configurations are possible. The angle 136 on one side can be acute, while the angle on the other side can be obtuse, in some cases.

FIG. 7 includes a line 306, which shows the admittance for an acoustic wave device 300 with an angled or slanted IDT electrode 108 and no raised frame (e.g., according to FIGS. 5 and 6), which is represented by line 306. The device 300 can provide an improved response between the resonant and anti-resonant frequencies (e.g., with suppressed transverse mode), but the device 300 can produce an unwanted or spurious response (e.g., indicated by 312) above the anti-resonant frequency. By comparison, the device 100 that includes the raised frame and corresponds to the line 302 in FIG. 7 can suppress the transverse mode, while avoiding the unwanted or spurious response 312 (e.g., above the anti-resonant frequency). In some embodiments, the fingers 114 and/or 116 can extend substantially perpendicular to the corresponding bus bar 110 and/or 112. The raised frame 124, 126 can be configured to suppress transverse mode without using a slanted IDT electrode 108. In some embodiments, the device 300 with a slanted IDT electrode 108 can include the raised frame structure 124, 126, which can extend along a slanted angle (e.g., along the ends of the fingers 114 and/or 116).

The raised frame structure 124, 126 can have a height 138 and a width 140, which can be the same for the first raised frame structure 124 and the second raised frame structure 126, in some implementations. The height 138 and/or width 140 of the raised frame structure 124, 126 can be determined relative to one or more dimensions of the IDT electrode 108, such as of the fingers 114 and/or 116, or relative to the primary or main resonance frequency or wavelength of the acoustic wave device. A distance L 142 can be taken from a side of a finger 114 to the same side of a neighboring finger 114, or from a side of a finger 116 to the same side of a neighboring finger 116. The distance L 142 can include the width of one first finger 114, the width of a gap between the first finger 114 and a second finger 116, the width of the second finger 116, and the width of a gap between the second finger 116 and a next first finger 114. The IDT electrode 108 can have a periodic structure following the pattern of first finger 114, gap, second finger 116, gap, repeating. The distance L 142 can correspond to one period of the repeating pattern of the IDT electrode 108. In some embodiments, the main resonant wavelength λ of the acoustic wave device 100 can be equal to, or influenced at least partially by, the distance L 142. The primary or main resonance frequency of the device can correspond to the resonant wavelength k.

The distance P 144 can correspond to a distance from a side of a first finger 114 to a same side of a second finger 116, or from a side of a second finger 116 to a same side of a first finger 114. The distance P 144 can include the width of one finger 114 or 116 and the width of one gap between fingers 114 and 116. In some cases, the widths of the first fingers 114 can be the same as the widths of the second fingers 116, and the distance P 144 can be half of the distance L 142. The distance D 146 can be the width of one finger 114, or one finger 116. The fingers 114 and 116 can have substantially the same width 146, although other configurations could have different widths for first fingers 114 and second fingers 116.

The height 138 of the raised frame structure 124 and/or 126 can be about 0.005 L, about 0.0075 L, about 0.01 L, about 0.015 L, about 0.02 L, about 0.025 L, about 0.03 L, about 0.035 L, about 0.04 L, or any values therebetween, or any ranges between any combination of these values (e.g., between about 0.01 L and about 0.3 L), although other heights could be used. The height 138 of the raised frame structure 124 and/or 126 can be about 0.5%, about 0.075%, about 1%, about 1.5%, about 2%, about 2.5%, about 3%, about 3.5%, or about 4% of the combined width of one finger 114, one finger 116, one gap between fingers 114 and 116, and one gap between fingers 116 and 114 (e.g., distance L 142), or any values or ranges between any of these numbers, although other configurations are possible. The height 138 of the raised frame structure 124 and/or 126 can be about 0.01 P, about 0.015 P, about 0.02 P, about 0.03 P, about 0.04 P, about 0.05 P, about 0.06 P, about 0.07 P, about 0.08 P, or any values therebetween, or any ranges between any combination of these values (e.g., between about 0.02 P and about 0.6 P), although other heights could be used. The height 138 of the raised frame structure 124 and/or 126 can be about 1%, about 1.5%, about 2%, about 3%, about 4%, about 5%, about 6%, about 7%, or about 8% of the combined width of one finger 114 or 116 and one gap between fingers 114, 116 (e.g., distance P 144), or any values or ranges between any of these numbers, although other configurations are possible.

The width 140 of the raised frame structure 124 and/or 126 can be about 0.4 L, about 0.5 L, about 0.6 L, about 0.7 L, about 0.8 L, about 0.9 L, about 1.0 L, about 1.1 L, about 1.2 L, about 1.3 L, about 1.4 L, about 1.5 L, about 1.6 L or any values therebetween, or any ranges between any combination of these values (e.g., between about 0.5 L and 1.0 L), although other widths could be used. The width 140 of the raised frame structure 124 and/or 126 can be about 40%, about 50%, about 60%, about 70%, about 80%, about 90%, about 100%, about 110%, about 120%, about 130%, about 140%, about 150%, or about 160% of the combined width of one finger 114, one finger 116, one gap between fingers 114 and 116, and one gap between fingers 116 and 114 (e.g., distance L 142), or any values or ranges between any of these numbers, although other configurations are possible. The width 140 of the raised frame structure 124 and/or 126 can be about 0.8 P, about 1 P, about 1.2 P, about 1.4 P, about 1.6 P, about 1.8 P, about 2.0 P, about 2.2 P, about 2.4 P, about 2.6 P, about 2.8 P, about 3 P, about 3.2 P, or any values therebetween, or any ranges between any combination of these values (e.g., between about 1.0 P and 2.0 P), although other widths could be used. The width 140 of the raised frame structure 124 and/or 126 can be about 80%, about 100%, about 120%, about 140%, about 160%, about 180%, about 200%, about 220%, about 240%, about 260%, about 280%, about 300%, or about 320% of the combined width of one finger 114 or 116 and one gap between fingers 114, 116 (e.g., distance P 144), or any values or ranges between any of these numbers, although other configurations are possible.

FIG. 8 shows a graph that compares the admittance for i) an acoustic wave device 200 that has no raised frame structure (represented by line 402), ii) an acoustic wave device 100 with a raised frame structure 124, 126 having a width 140 of 1.0 L and a height of 0.01 L (represented by Line 404), and iii) an acoustic wave device 100 with a raised frame structure 124, 126 having a width 140 of 1.0 L and a height of 0.03 L (represented by Line 406).

Comparing line 404 to line 406, it can be seen that increasing the raised frame height 138 (e.g., from 0.01 L to 0.03 L) can improve the response (e.g., between the resonant and anti-resonant frequencies), such as by improving suppression of spurious transverse mode. In some embodiments, increasing the raised frame width 140 (e.g., from 0.5 L to 1.0 L) can improve the response (e.g., between the resonant and anti-resonant frequencies), such as by improving suppression of spurious transverse mode.

A duty factor DF of the IDT electrode 108 can be an indication of how much of the active area is occupied by the fingers 114, 116. The duty factor DF can be determined as a ratio or percentage of the area of the fingers 114, 116 in the active region 130 to the total area of the active region 130. For example a duty factor of 0 can indicate that no area is covered by the fingers, 0.5 can indicate that half the active area is covered by the fingers, and 1.0 would indicate that all the active area is covered by the fingers. By way of example, the duty factor DF can be determined using the equation DF=D/P. Dividing the distance D 146 by the distance P 144 can provide the duty factor DF when the width of the fingers 114 is the same as the width of the fingers 116 and the width of the gaps between the fingers 114 and 116 are the same. The duty factor DF can be determined using the equation DF=(D1+D2)/L, where D1 is the width of a first finger 114, where D2 is the width of a second finger 116, and where L is the width 142 discussed above (e.g., across one first finger 114, one second finger 116, one gap between fingers 114 and 116, and one gap between fingers 116 and 114). The duty factor DF of the device 100 can be larger than about 0.45, about 0.5, about 0.55, about 0.6, about 0.65, about 0.7, about 0.75, or any values therebetween, or any ranges between any combination of these numbers, although other configurations are possible. In some implementations, a lower duty factor DF can improve transverse mode suppression, but a lower DF can result in a larger IDT electrode 108 and increased filter size (e.g., due to lower static capacitance). The raised frame structure 124, 126 disclosed herein can provide for transverse mode suppression with a relatively high duty factor DF (e.g., above 0.5, meaning the fingers 114, 116 occupy more than half the area of the active region 130), which can reduce the size of the acoustic device 100 and associated filters. The width of one of the finger 114, 116 can be larger than the width of a gap between neighboring fingers 114, 116.

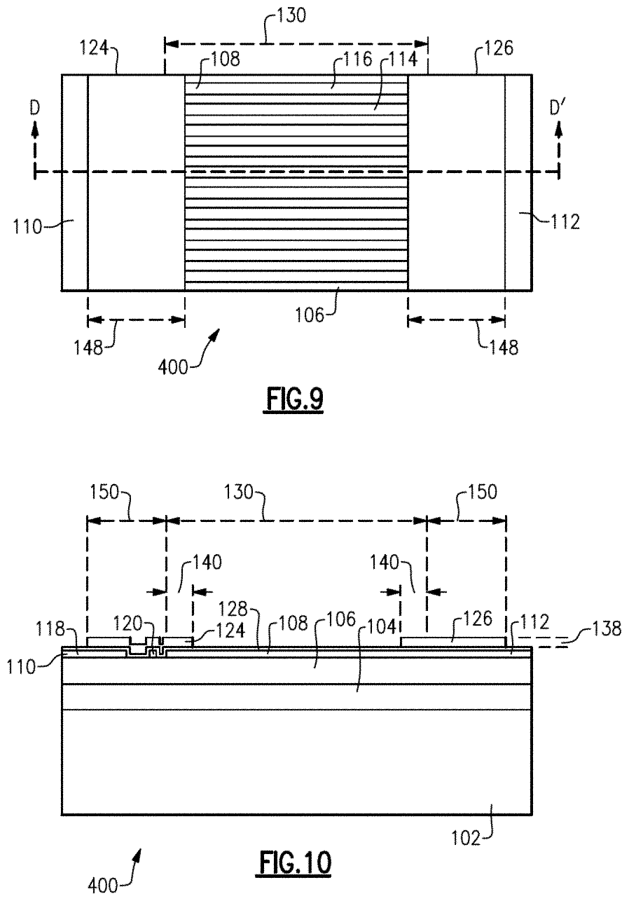

FIG. 9 shows a plan view of an example embodiment of an acoustic wave device 400. FIG. 10 is a cross-sectional view of the acoustic wave device 400 of FIG. 9 taken through the line from D to D′. The device 400 can be similar to the other embodiments disclosed herein, except as discussed herein. In some implementations, the raised frame structure 124, 126 can extend outward past the active region 130. The first raised frame structure 124 can extend past the ends of the second fingers 116. The first raised frame structure 124 can cover some of, a majority of, or all of the first bus bar 110. The first raised frame structure 124 can cover the inner or secondary portion 120 of the bus bar 110. The first raised frame structure 124 can cover some of, a majority of, or all of the outer or main portion 118 of the first bus bar 110. The second raised frame structure 126 can extend past the ends of the first fingers 114. The second raised frame structure 126 can cover some of, a majority of, or all of the second bus bar 112. The second raised frame structure 126 can cover the inner or secondary portion 120 of the second bus bar 112. The second raised frame structure 126 can cover some of, a majority of, or all of the outer or main portion 118 of the second bus bar 112. The raised frame structures 124, 126 can cover the respective gaps between fingers 116, 114 and bus bars 110, 112. In some embodiments, the raised frame structures 124, 126 can have recessed areas (as can be seen in FIG. 10 for the first raised frame 124), such as where the material of the raised frame structure 124, 126 drops into the gap between the respective fingers 116, 114 and bus bars 110, 112, and/or into the gap 122 between the outer or main bus bar section 118 and the inner or secondary bus bar section 120. In some embodiments, the raised frame structure 124, 126 can have a flat upper surface, even over the gaps discussed above. For example, the raised frame structure 124, 126 can be thicker at the gaps in the conductive layer that forms the IDT electrode 108.

The raised frame structure 124, 126 can have an overall width 148, which can include a width 140 of an inner portion of the raised frame structure 124, 126 that is disposed in the active region 130 (e.g., where the fingers 114, 116 overlap), and a width 150 of an outer portion that is disposed outside the active region 130. The values and ranges for the width 140 of the raised frame portion discussed here (e.g., about 0.4 L to about 1.2 L) can correspond to the width 140 of the portion of the raised frame structure 124, 126 that is in the active region 130, and/or the distance that the raised frame portion 124, 126 extends inward past the ends of the corresponding fingers 116, 114. In some implementations, the additional width 150 of the raised frame 124, 126 outside the active region can have reduced influence over the performance of the acoustic wave device 400. In some implementations, the width 150 (e.g., outside the active region) can be larger than the width 140 (e.g., inside the active region), although other configurations are possible and the width 150 could be smaller than the width 140.

FIG. 11 is a cross-sectional view of an example embodiment of an acoustic wave device 500, which can be similar to the other embodiments disclosed herein, except as discussed herein. For the device 500, the passivation layer 128 can be omitted. The raised frame structure 124, 126 can be formed (e.g., deposited) directly onto the IDT electrode 108, in some embodiments.

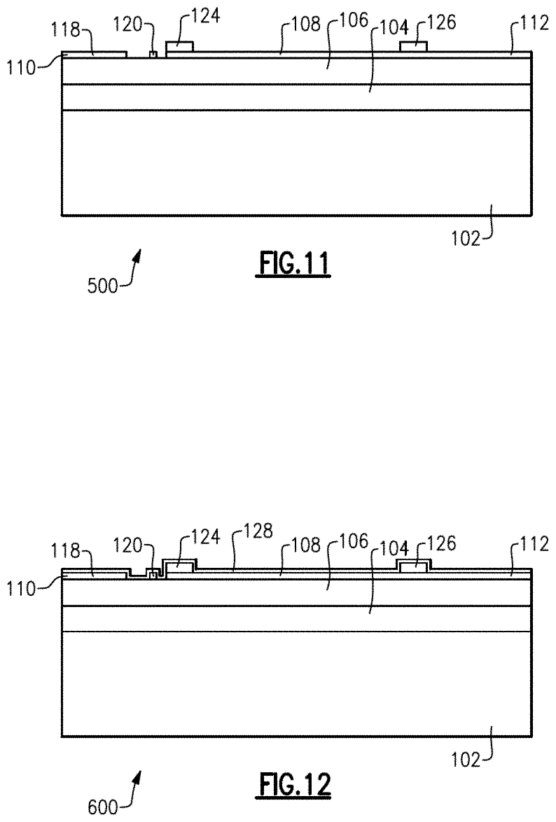

FIG. 12 is a cross-sectional view of an example embodiment of an acoustic wave device 600, which can be similar to the other embodiments disclosed herein, except as discussed herein. For the device 600, the passivation layer 128 can be formed (e.g., deposited) over the raised frame structure 124, 126. For example, the raised frame structure 124, 126 can be formed (e.g., deposited) directly onto or over the IDT electrode 108, and the passivation layer can be formed (e.g., deposited) directly onto or over the raised frame structure 124, 126. The raised frame structure 124, 126 can be patterned or otherwise shaped, so that the passivation layer 128 contacts the IDT electrode 108 are at least some areas that are not covered by the raised frame structure 124, 126.

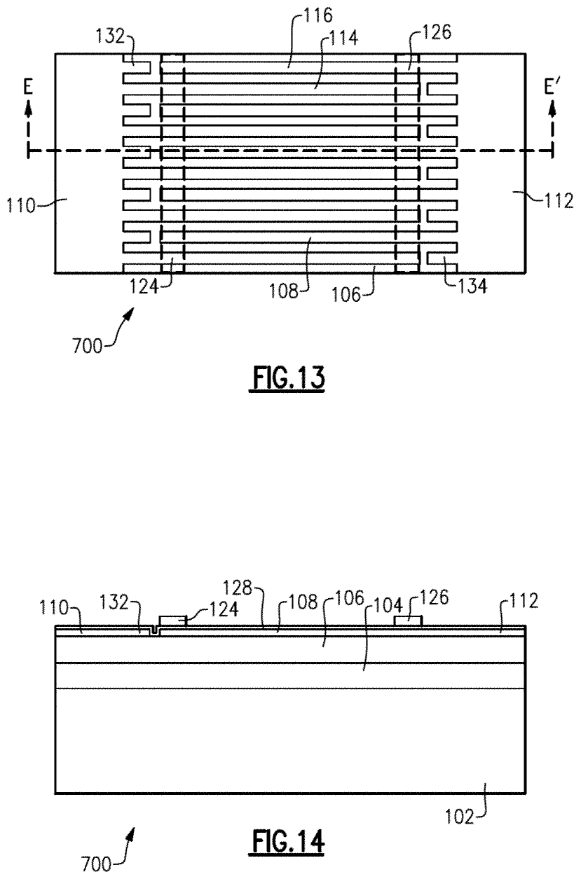

FIG. 13 shows a plan view of an example embodiment of an acoustic wave device 700. FIG. 14 is a cross-sectional view of the acoustic wave device 400 of FIG. 9 taken through the line from E to E′. The device 700 can be similar to the other embodiments disclosed herein, except as discussed herein. The IDT electrode 108 can have interdigitated first fingers 114 and second fingers 116. The IDT electrode 108 can include first dummy fingers 132, which can extend from the first bus bar 110 towards the fingers 116 or second bus bar 112. The first set of dummy fingers 132 can be positioned between corresponding first fingers 114. The first dummy fingers 132 can be shorter than the first fingers 114. The first dummy fingers 132 can be aligned or collinear with the opposing second fingers 116. The first dummy fingers 132 can extend substantially parallel to the first fingers 114, or substantially perpendicular to the first bus bar 110. The IDT electrode 108 can include second dummy fingers 134, which can extend from the second bus bar 112 towards the fingers 114 or first bus bar 112. The second set of dummy fingers 134 can be positioned between corresponding second fingers 116. The second dummy fingers 134 can be shorter than the second fingers 116. The second dummy fingers 134 can be aligned or collinear with the opposing first fingers 116. The second dummy fingers 134 can extend substantially parallel to the second fingers 116, or substantially perpendicular to the second bus bar 112. In some cases, the dummy fingers 132, 134 can be omitted. In FIG. 13, the raised frame structure(s) 124, 126 are shown as dashed lines, to facilitate visibility of the underlying components.

FIG. 15 is a plan view of an example embodiment of an acoustic wave device 800, which can be similar to the other embodiments disclosed herein, except as discussed herein. For the device 800, the dummy fingers 132, 134 are omitted, and the secondary bus bar 120 is omitted. In FIG. 15, the raised frame structure(s) 124, 126 are shown as dashed lines, to facilitate visibility of the underlying components.

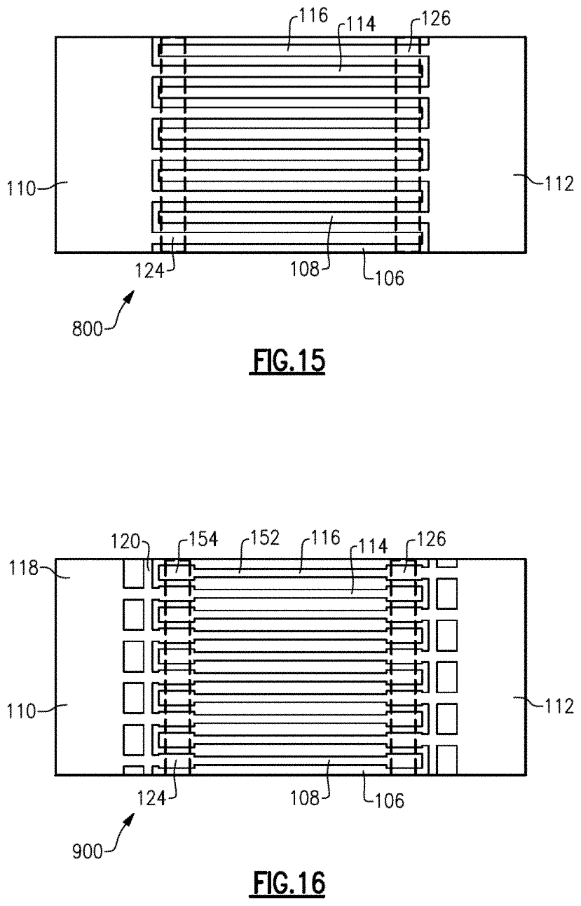

FIG. 16 is a plan view of an example embodiment of an acoustic wave device 900, which can be similar to the other embodiments disclosed herein, except as discussed herein. In FIG. 16, the raised frame structure(s) 124, 126 are shown as dashed lines, to facilitate visibility of the underlying components. The fingers 114 and/or 116 can include a stem portion 152 and a head portion 154. The head portion 154 can be wider than the stem portion 152. The head portion 154 can be about 25%, about 30%, about 40%, about 50%, about 60%, about 70%, about 75%, about 80%, about 90%, about 100%, about 125%, about 150%, about 175%, about 200%, about 250%, or about 300% wider than the stem portion 152, or any values therebetween, or any ranges between any combination of these values, although other configurations are possible. The head portion 154 can be disposed at the end of the finger 114 or 116, such as the end closest to the opposing bus bar 112, 110. The first raised frame portion 124 can at least partially overlap with the head portions 154 of the second arms 116. The second raised frame portion can at least partially overlap with the head portions 154 of the first fingers 114. The head portions 154 can have a length that is greater than a width of the corresponding raised frame structure 124, 126, and in some embodiments, a portion of the head portions 154 can extend past the raised frame structure 124 on one or both sides of the raised frame structure 124. In the embodiment of FIG. 16, the ends of the head portions 154 (e.g., furthest from the connection to the bus bar 110, 112) can extend past the edge of the raised frame structure 124, 126. In some embodiments, the raised frame portion 124, 126 can cover, or align substantially flush with, the ends of the corresponding fingers 116, 114. In some embodiments, the raised frame portions 124, 126 can cover the head portions 154 of the fingers 116, 114.

FIG. 17 is a plan view of an example embodiment of an acoustic wave device 1000, which can be similar to the other embodiments disclosed herein, except as discussed herein. In FIG. 17, the IDT electrode 108 can include first dummy fingers 132, which can extend from the first bus bar 110 towards the fingers 116 or toward the second bus bar 112. The first set of dummy fingers 132 can be positioned between corresponding first fingers 114. The first dummy fingers 132 can be shorter than the first fingers 114. The first dummy fingers 132 can be aligned with the opposing second fingers 116. The IDT electrode 108 can include second dummy fingers 134, which can extend from the second bus bar 112 towards the first fingers 114 or toward the first bus bar 112. The second set of dummy fingers 134 can be positioned between corresponding second fingers 116. The second dummy fingers 134 can be shorter than the second fingers 116. The second dummy fingers 134 can be aligned with the opposing first fingers 116. The dummy fingers 132, 134 can be used in combination with the secondary bus bar 120, as shown in FIG. 17. The first dummy fingers 132 can extend from the secondary bus bar 120 of the first bus bar 110. The second dummy fingers 134 can extend from the secondary bus bar 120 of the second bus bar 112.

The main bus bar section 118 can be electrically coupled to the secondary bus bar section 120 by one or more electrical interconnections, such as one or more gap lines 121, which can extend across the gap 122 between the main bus bar section 118 and the secondary bus bar section 120. The gap lines 121 can be electrical material, such as formed as the same layer as the rest of the IDT electrode 108. The gap lines 121 of the first bus bar 110 can align with the first fingers 114, and the gap lines 121 of the second bus bar 112 can align with the second fingers 116. For example, a first finger 114 can extend from the secondary bus bar section 120 of the first bus bar 110 in a first direction (e.g., towards the second bus bar 112), and a corresponding gap line 121 can extend from the secondary bus bar section 120 of the first bus bar 110 in a second direction (e.g., towards the first section 118 of the first bus bar 110). Similarly, a second finger 116 can extend from the secondary bus bar section 120 of the second bus bar 112 in the second direction (e.g., towards the first bus bar 110), and a corresponding gap line 121 can extend from the secondary bus bar section 120 of the second bus bar 112 in the first direction (e.g., towards the first section 118 of the second bus bar 112). A line can extend along the finger 114 or 116, across the secondary bus bar section 120, and along the gap line 121. In some cases, a centerline of the gap line 121 can be substantially collinear with a centerline of the corresponding finger 114 or 116. In other configurations, the gap lines 121 can be at other positions, such as aligned with corresponding dummy fingers 132, 134. The gap lines 121 can divide the gap 122 into gap sections, as can be seen in FIG. 17. The gap lines 121 can have a width 160 that is narrower than a width 146 of the fingers 114 or 116. The narrower gap lines 121 and/or the dummy fingers 132, 134 can provide improved acoustic wave trapping and/or improved Q values. The fingers 114 and/or 116 can be thicker than the gap lines 121. In some cases, the configuration of FIG. 17 can permit the width of the fingers 114 and/or 116 to be increased while providing adequate wave trapping and Q values. The thicker fingers 114 and/or 116 can reduce the size of the acoustic wave device 1000 and associated filters. In some cases, thicker IDT fingers 114, 116 can provide slower wave velocity and higher reflective coefficients, which can facilitate trapping of the acoustic energy (e.g., with a smaller number of grating reflectors in some cases).

The acoustic wave device 1000 can have various dimensions, as discussed herein. Some dimensions of certain embodiments are provided below with reference to distance L. The distance L can be the combined width 142 of one finger 114, one finger 116, one gap between fingers 114 and 116, and one gap between fingers 116 and 114. In some embodiments, the main resonant wavelength λ of the acoustic wave device 100 can be equal to, or influenced at least partially by, the distance L 142. The width 140 of the raised frame structure 124 and/or 126 can be about 0.5 L to about 1.5 L, although other widths could be used as disclosed herein. The fingers 114 and/or 116 can have a width 146 of about 0.2 L, about 0.25 L, about 0.3 L, about 0.35 L, or any values or range therebetween, although other widths could be used. The gap lines 121 can have a width 160 of about 0.1 L, about 0.15 L, about 0.2 L, about 0.25 L, about 0.3 L, about 0.35 L, or more, or any values or range therebetween. In some cases, the width 160 of the gap lines 121 can be smaller than the width 146 of the fingers 114 and/or 116. In some cases, the gap lines 121 can effectively fill the gaps 122 to form unitary bus bars 110, 112, as shown for example in FIG. 13. The gap 122 between the main bus bar section 118 and the secondary bus bar section 120 can have a width or thickness 162 of about 0.25 L, about 0.3 L, about 0.4 L, about 0.5 L, about 0.6 L, about 0.75 L, about 1 L, about 1.25 L, about 1.5 L, about 1.75 L, about 2 L, about 2.25 L, or any values or ranges therebetween (e.g., between 0.3 L and 2 L), although other values could be used in some cases. The secondary bus bar section 120 can have a width or thickness 164 of about 0.1 L, about 0.15 L, about 0.2 L, about 0.25 L, about 0.3 L, about 0.35 L, or any values or ranges between these values, although other configurations could be used.

The dummy fingers 132 and/or 134 can have a width or thickness 166 of about 0.1 L, about 0.15 L, about 2 L, about 2.5 L, about 3 L, about 4 L, about 5 L, about 5.5 L, about 6 L, about 6.5 L, about 7 L, or any values or ranges therebetween, although other sizes could be used. In some cases the thickness 166 of the dummy fingers 132 and/or 134 can be larger than the thickness 146 of the corresponding fingers 114 and/or 116. The dummy fingers 132 and/or 134 can have a length 168 of about 0.05 L, about 0.1 L, about 0.15 L, about 2 L, about 2.5 L, about 3 L, about 3.5 L, about 4 L or any values or ranges therebetween, although other sizes could be used. The dummy fingers 132 and/or 134 can be spaced apart from the ends of the corresponding fingers 114 and/or 116 by gaps that can have a width 170 of about 0.05 L, about 0.1 L, about 0.15 L, about 2 L, about 2.5 L, about 3 L, about 3.5 L, about 4 L or any values or ranges therebetween, although other sizes could be used.

The various features of the acoustic wave devices disclosed herein can be combined. For example, any of the acoustic wave devices can be a SAW device or an MPS device. Various acoustic wave devices can have a bus bar with a primary portion 118 and a secondary portion 120. Various acoustic wave devices can raised frame structure(s) 124, 126 that can extend outward past the active region 130, while other embodiments can have raised frame structure(s) that are contained within the active region 130. Various acoustic wave devices can have a passivation layer 128, as disclosed, or that passivation layer 128 can be omitted. Various acoustic wave devices can include dummy fingers, in some implementations. Various acoustic wave devices can have fingers with head portions that are wider than shaft portions.

The resonator devices disclosed herein can be implemented in acoustic wave filters. In certain applications, the acoustic wave filters can be band pass filters arranged to pass a radio frequency band and attenuate frequencies outside of the radio frequency band. Two or more acoustic wave filters can be coupled together at a common node and arranged as a multiplexer, such as a duplexer.

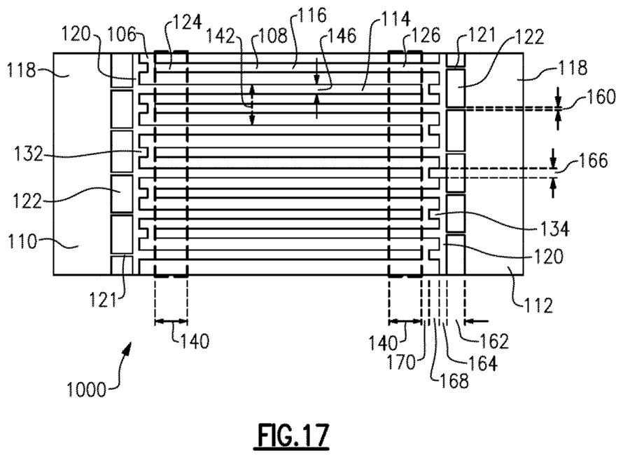

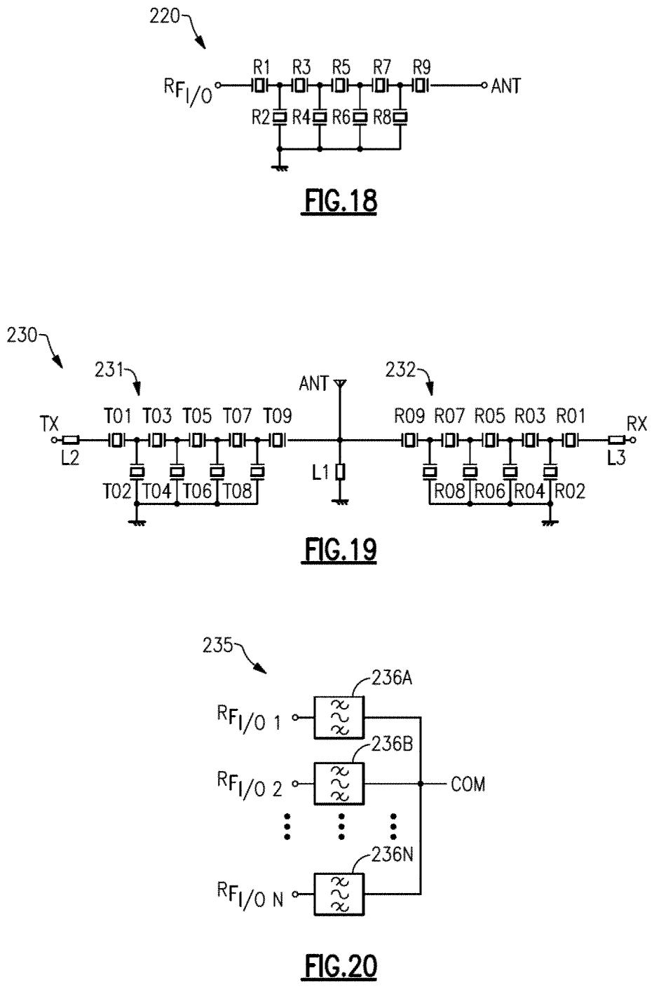

FIG. 18 is a schematic diagram of an example of an acoustic wave ladder filter 220. The acoustic wave ladder filter 220 can be a transmit filter or a receive filter. The acoustic wave ladder filter 220 can be a band pass filter arranged to filter a radio frequency signal. The acoustic wave filter 220 can include series resonators R1, R3, R5, R7, and R9 and shunt resonators R2, R4, R6, and R8 coupled between a radio frequency input/output port RFI/O and an antenna port ANT. The radio frequency input/output port RFI/O can be a transmit port in a transmit filter or a receive port in a receive filter. One or more of the illustrated acoustic wave resonators can be a surface acoustic wave resonator in accordance with any suitable principles and advantages discussed herein. An acoustic wave ladder filter can include any suitable number of series resonators and any suitable number of shunt resonators.

An acoustic wave filter can be arranged in any other suitable filter topology, such as a lattice topology or a hybrid ladder and lattice topology. A surface acoustic wave resonator in accordance with any suitable principles and advantages disclosed herein can be implemented in a band pass filter. In some other applications, a surface acoustic wave resonator in accordance with any suitable principles and advantages disclosed herein can be implemented in a band stop filter.

FIG. 19 is a schematic diagram of an example of a duplexer 230. The duplexer 230 can include a transmit filter 231 and a receive filter 232 coupled to each other at an antenna node ANT. A shunt inductor L1 can be connected to the antenna node ANT. The transmit filter 231 and the receive filter 232 can both be acoustic wave ladder filters in the duplexer 230.

The transmit filter 131 can filter a radio frequency signal and provide a filtered radio frequency signal to the antenna node ANT. A series inductor L2 can be coupled between a transmit input node TX and the acoustic wave resonators of the transmit filter 131. The illustrated transmit filter 131 can include acoustic wave resonators T01 to T09. One or more of these resonators can be surface acoustic wave resonator in accordance with any suitable principles and advantages disclosed herein. The illustrated receive filter can include acoustic wave resonators R01 to R09. One or more of these resonators can be a surface acoustic wave resonator in accordance with any suitable principles and advantages disclosed herein. The receive filter can filter a radio frequency signal received at the antenna node ANT. A series inductor L3 can be coupled between the resonator and a receive output node RX. The receive output node RX of the receive filter provides a radio frequency receive signal.

FIG. 20 is a schematic diagram of a multiplexer 235 that includes an acoustic wave filter according to an embodiment. The multiplexer 235 can include a plurality of filters 236A to 236N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. Each of the illustrated filters 236A, 236B, and 236N can be coupled between the common node COM and a respective input/output node RFI/O1, RFI/O2, and RFI/ON.

In some instances, all filters of the multiplexer 235 can be receive filters. According to some other instances, all filters of the multiplexer 235 can be transmit filters. In various applications, the multiplexer 235 can include one or more transmit filters and one or more receive filters. Accordingly, the multiplexer 235 can include any suitable number of transmit filters and any suitable number of receive filters. Each of the illustrated filters can be band pass filters having different respective pass bands.

The multiplexer 235 is illustrated with hard multiplexing with the filters 236A to 236N having fixed connections to the common node COM. In some other applications, one or more of the filters of a multiplexer can be electrically connected to the common node by a respective switch. Any of such filters can include a surface acoustic wave resonator according to any suitable principles and advantages disclosed herein.

A first filter 236A can be an acoustic wave filter having a first pass band and arranged to filter a radio frequency signal. The first filter 236A can include one or more surface acoustic wave resonators according to any suitable principles and advantages disclosed herein. A second filter 236B has a second pass band. In some embodiments, a raised frame structure of one or more surface acoustic wave resonators of the first filter 236A can move a raised frame mode of the one or more surface acoustic wave resonators away from the second passband. This can increase a reflection coefficient (Gamma) of the first filter 236A in the pass band of the second filter 236B. The raised frame structure of the surface acoustic wave resonator of the first filter 236A can also move the raised frame mode away from the passband of one or more other filters of the multiplexer 235.

In certain instances, the common node COM of the multiplexer 235 can be arranged to receive a carrier aggregation signal including at least a first carrier associated with the first passband of the first filter 236A and a second carrier associated with the second passband of the second filter 236B. A multi-layer raised frame structure of a surface acoustic wave resonator of the first filter 236A can maintain and/or increase a reflection coefficient of the first filter 236A in the second passband of the second filter 236B that is associated with the second carrier of the carrier aggregation signal.

The filters 236B to 236N of the multiplexer 235 can include one or more acoustic wave filters, one or more acoustic wave filters that include at least one surface acoustic wave resonator with a raised frame structure, one or more LC filters, one or more hybrid acoustic wave LC filters, or any suitable combination thereof.

The acoustic wave resonators disclosed herein can be implemented in a variety of packaged modules. Some example packaged modules will now be discussed in which any suitable principles and advantages of the surface acoustic wave devices disclosed herein can be implemented. The example packaged modules can include a package that encloses the illustrated circuit elements. The illustrated circuit elements can be disposed on a common packaging substrate. The packaging substrate can be a laminate substrate, for example. FIGS. 21, 22A, 22B, and 23 are schematic block diagrams of illustrative packaged modules according to certain embodiments. Certain example packaged modules can include one or more radio frequency amplifiers, such as one or more power amplifiers and/or one or more low noise amplifiers. Any suitable combination of features of these modules can be implemented with each other. While duplexers are illustrated in the example packaged modules of FIGS. 21, 22A, and 23, any other suitable multiplexer that includes a plurality of acoustic wave filters coupled to a common node can be implemented instead of one or more duplexers. For example, a quadplexer can be implemented in certain applications. Alternatively or additionally, one or more filters of a packaged module can be arranged as a transmit filter or a receive filter that is not included in a multiplexer.

FIG. 21 is a schematic block diagram of an example module 240 that includes duplexers 241A to 241N and an antenna switch 242. One or more filters of the duplexers 241A to 241N can include any suitable number acoustic wave resonators in accordance with any suitable principles and advantages discussed herein. Any suitable number of duplexers 241A to 241N can be implemented. The antenna switch 242 can have a number of throws corresponding to the number of duplexers 241A to 241N. The antenna switch 242 can electrically couple a selected duplexer to an antenna port of the module 240.

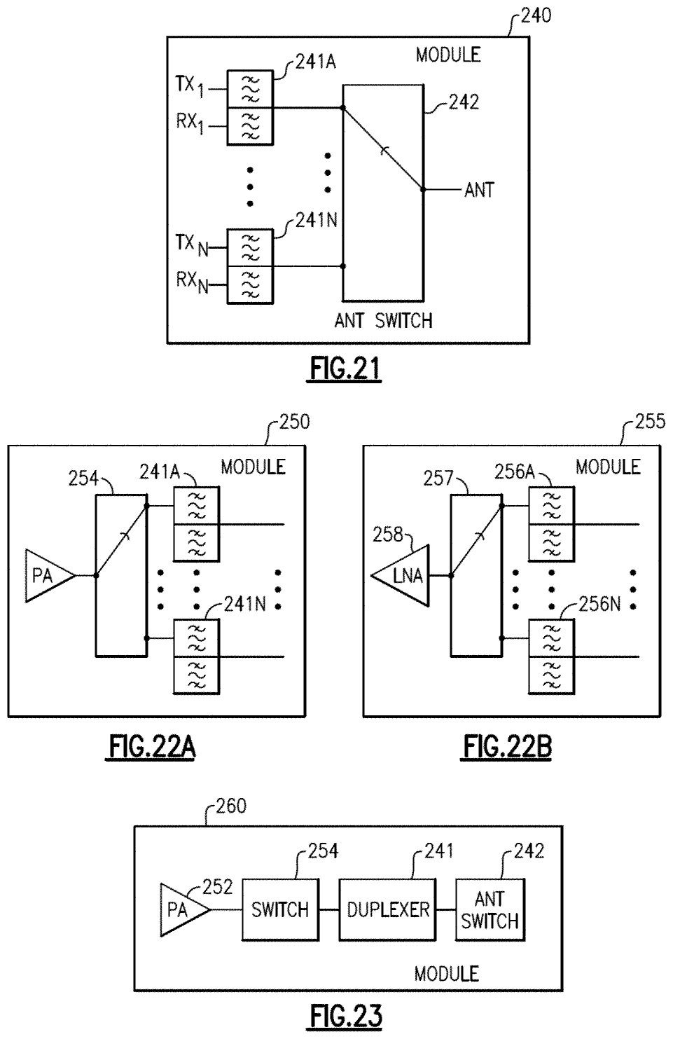

FIG. 22A is a schematic block diagram of an example module 250 that includes a power amplifier 252, a radio frequency switch 254, and duplexers 241A to 241N in accordance with one or more embodiments. The power amplifier 252 can amplify a radio frequency signal. The radio frequency switch 254 can be a multi-throw radio frequency switch. The radio frequency switch 254 can electrically couple an output of the power amplifier 252 to a selected transmit filter of the duplexers 241A to 241N. One or more filters of the duplexers 241A to 241N can include any suitable number of surface acoustic wave resonators in accordance with any suitable principles and advantages discussed herein. Any suitable number of duplexers 241A to 241N can be implemented.

FIG. 22B is a schematic block diagram of an example module 255 that includes filters 256A to 256N, a radio frequency switch 257, and a low noise amplifier 258 according to one or more embodiments. One or more filters of the filters 256A to 256N can include any suitable number of surface acoustic wave resonators in accordance with any suitable principles and advantages disclosed herein. Any suitable number of filters 256A to 256N can be implemented. The illustrated filters 256A to 256N can be receive filters. In some embodiments (not illustrated), one or more of the filters 256A to 256N can be included in a multiplexer that also includes a transmit filter. The radio frequency switch 257 can be a multi-throw radio frequency switch. The radio frequency switch 257 can electrically couple an output of a selected filter of filters 256A to 256N to the low noise amplifier 257. In some embodiments (not illustrated), a plurality of low noise amplifiers can be implemented. The module 255 can include diversity receive features in certain applications.

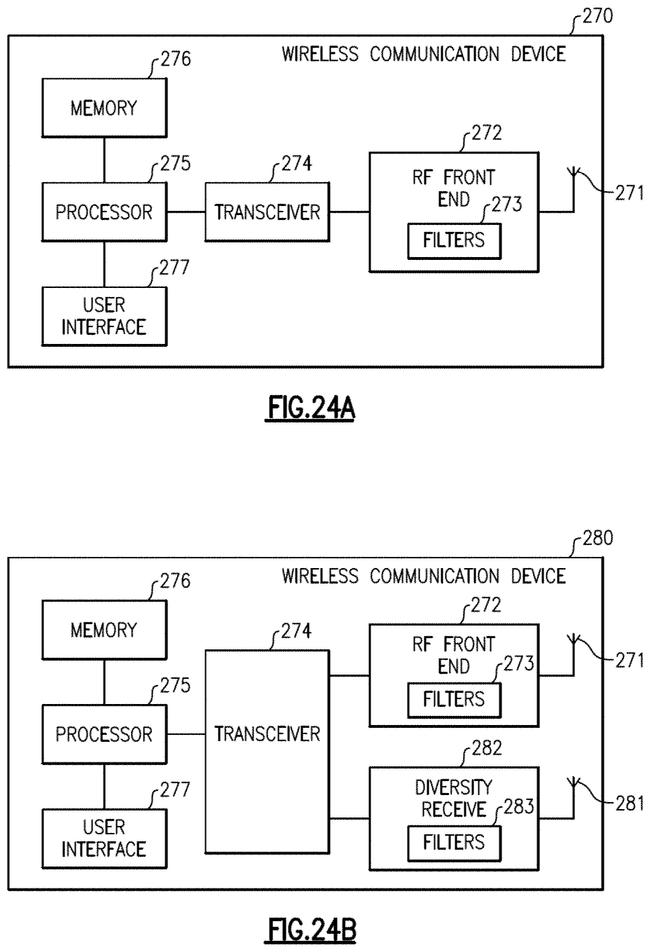

FIG. 23 is a schematic block diagram of an example module 260 that includes a power amplifier 252, a radio frequency switch 254, and a duplexer 241 that includes surface acoustic wave device in accordance with one or more embodiments, and an antenna switch 242. The module 260 can include elements of the module 240 and elements of the module 250.

One or more filters with any suitable number of surface acoustic devices can be implemented in a variety of wireless communication devices. FIG. 24A is a schematic block diagram of an example wireless communication device 270 that includes a filter 273 with one or more acoustic wave resonators in accordance with any suitable principles and advantages disclosed herein. The wireless communication device 270 can be any suitable wireless communication device. For instance, a wireless communication device 270 can be a mobile phone, such as a smart phone. As illustrated, the wireless communication device 270 includes an antenna 271, a radio frequency (RF) front end 272 that includes filter 273, an RF transceiver 274, a processor 275, a memory 276, and a user interface 277. The antenna 271 can transmit RF signals provided by the RF front end 272. The antenna 271 can provide received RF signals to the RF front end 272 for processing.

The RF front end 272 can include one or more power amplifiers, one or more low noise amplifiers, RF switches, receive filters, transmit filters, duplex filters, filters of a multiplexer, filters of a diplexers or other frequency multiplexing circuit, or any suitable combination thereof. The RF front end 272 can transmit and receive RF signals associated with any suitable communication standards. Any of the acoustic wave resonators disclosed herein can be implemented in filters 273 of the RF front end 272.

The RF transceiver 274 can provide RF signals to the RF front end 272 for amplification and/or other processing. The RF transceiver 274 can also process an RF signal provided by a low noise amplifier of the RF front end 272. The RF transceiver 274 is in communication with the processor 275. The processor 275 can be a baseband processor. The processor 275 can provide any suitable base band processing functions for the wireless communication device 270. The memory 276 can be accessed by the processor 275. The memory 276 can store any suitable data for the wireless communication device 270. The processor 275 is also in communication with the user interface 277. The user interface 277 can be any suitable user interface, such as a display.

FIG. 24B is a schematic diagram of a wireless communication device 280 that includes filters 273 in a radio frequency front end 272 and second filters 283 in a diversity receive module 282. The wireless communication device 280 is like the wireless communication device 270 of FIG. 24A, except that the wireless communication device 280 also includes diversity receive features. As illustrated in FIG. 24B, the wireless communication device 280 can include a diversity antenna 281, a diversity module 282 configured to process signals received by the diversity antenna 281 and including filters 283, and a transceiver 274 in communication with both the radio frequency front end 272 and the diversity receive module 282. One or more of the second filters 283 can include a surface acoustic wave resonator in accordance with any suitable principles and advantages disclosed herein.

Acoustic wave devices disclosed herein can be included in a filter and/or a multiplexer arranged to filter a radio frequency signal in a fifth generation (5G) New Radio (NR) operating band within Frequency Range 1 (FR1). FR1 can from 410 megahertz (MHz) to 7.125 gigahertz (GHz), for example, as specified in a current 5G NR specification. A filter arranged to filter a radio frequency signal in a 5G NR FR1 operating band can include one or more acoustic wave resonators be implemented in accordance with any suitable principles and advantages disclosed herein.

5G NR carrier aggregation specifications can present technical challenges. For example, 5G carrier aggregations can have wider bandwidth and/or channel spacing than fourth generation (4G) Long Term Evolution (LTE) carrier aggregations. Carrier aggregation bandwidth in certain 5G FR1 applications can be in a range from 120 MHz to 400 MHz, such as in a range from 120 MHz to 200 MHz. Carrier spacing in certain 5G FR1 applications can be up to 100 MHz. Acoustic wave resonators as disclosed herein can have improved heat management, in some embodiments.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

While certain embodiments have been described, these embodiments have been presented by way of example only, and are not intended to limit the scope of the disclosure. Indeed, the novel resonators, devices, modules, apparatus, methods, and systems described herein may be embodied in a variety of other forms. Furthermore, various omissions, substitutions and changes in the form of the resonators, devices, modules, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. An acoustic wave device comprising:
a substrate;
a piezoelectric layer;
an interdigital transducer electrode including a plurality of fingers separated by gaps, the piezoelectric layer disposed between the substrate and the interdigital transducer electrode; and
a raised frame structure, the interdigital transducer disposed between the piezoelectric layer and the raised frame structure.

2. The acoustic wave device of claim 1, including an active region where the plurality of fingers overlap, a first raised frame structure extending along a first side of the active region, and a second raised frame structure extending along a second side of the active region opposite the first side.

3. The acoustic wave device of claim 2, wherein a width of an inner region between the first raised frame structure and the second raised frame structure is larger than a combined width of the first raised frame structure and the second raised frame structure.

4. The acoustic wave device of claim 2, wherein the fingers occupy a first area of the active region, the gaps between the fingers occupy a second area of the active region, and the first area is larger than the second area.

5. The acoustic wave device claim 1, wherein a width of one of the fingers divided by a combined width of the finger and one of the gaps provides a duty function that is between about 0.5 and about 0.75.

6. The acoustic wave device of claim 1, wherein the raised frame structure has a height that is between about 1% and about 8% of a combined width of one of the fingers and one of the gaps.

7. The acoustic wave device of any claim 1, wherein the raised frame structure has a width that is between about 80% and about 300% of a combined width of one of the fingers and one of the gaps.

8. The acoustic wave device of claim 1, wherein the interdigital transducer electrode includes a main bus bar portion and a secondary bus bar portion that is spaced apart from the main bus bar portion, a first set of the plurality of fingers extending from the secondary bus bar portion.

9. The acoustic wave device of claim 8, wherein at least one gap line extends between and electrically interconnect the main bus bar portion and the secondary bus bar portion, the gap line having a width that is smaller than a width of one of the plurality of fingers.

10. The acoustic wave device of claim 9, wherein the interdigital transducer electrode includes a plurality of dummy fingers that are shorter than the plurality of fingers.

11. An acoustic wave device comprising:
a substrate;
a piezoelectric layer;
a first electrode that includes a first bus bar and a first plurality of fingers extending from the first bus bar;
a second electrode that includes a second bus bar and a second plurality of fingers extending from the second bus bar, the second plurality of fingers interdigitated with the first plurality of fingers; and
a raised frame structure.

12. The acoustic wave device of claim 11, wherein the raised frame structure includes a first raised frame disposed over ends of the first fingers and a second raised frame over ends of the second fingers.

13. The acoustic wave device of claim 11, further comprising a passivation layer disposed between the raised frame structure and the first and second electrodes.

14. The acoustic wave device of claim 13, wherein the raised frame structure includes silicon dioxide and the passivation layer includes silicon nitride.

15. The acoustic wave device of claim 11, wherein a width of one of the first plurality of fingers is larger than the space between that finger and an adjacent one of the second plurality of fingers.

16. The acoustic wave device of claim 11, wherein a first side of one of the first plurality of fingers is spaced away from a first side of a next one of the first plurality of fingers by a distance L, the raised frame structure having a height that is between about 0.005 times and about 0.04 times the distance L.

17. The acoustic wave device of claim 11, wherein a first side of one of the first plurality of fingers is spaced away from a first side of a next one of the first plurality of fingers by a distance L, the raised frame structure having a width that is between about 0.4 times and about 1.5 times the distance L.

18. The acoustic wave device of claim 11, wherein the first bus bar includes a main portion and a secondary portion that is inward of the main portion and spaced apart from the main portion, and the second bus bar includes a main portion and a secondary portion that is inward of the main portion and spaced apart from the main portion.

19. The acoustic wave device of claim 18, wherein the first bus bar includes a plurality of first gap lines that extend from the main portion to the secondary portion of the first bus bar, the first gap lines having widths that are smaller than widths of the first plurality of fingers, and the second bus bar include a plurality of second gap lines that extend from the main portion to the secondary portion of the second bus bar, the second gap lines having widths that are smaller than widths of the second plurality of fingers.

20. The acoustic wave device of claim 19, wherein a first side of one of the first plurality of fingers is spaced away from a first side of a next one of the first plurality of fingers by a distance L, the first gap line having widths between about 0.1 times the distance L and about 0.2 times the distance L.

21. The acoustic wave device of claim 19, further comprising:
a first plurality of dummy fingers extending from the first bus bar, the first plurality of dummy fingers shorter than the first plurality of fingers, the first plurality of dummy fingers aligned with the second plurality of fingers; and
a second plurality of dummy fingers extending from the second bus bar, the second plurality of dummy fingers shorter than the second plurality of fingers, the second plurality of dummy fingers aligned with the first plurality of fingers.

22. The acoustic wave device of claim 21, wherein a first side of one of the first plurality of fingers is spaced away from a first side of a next one of the first plurality of fingers by a distance L, the first plurality of dummy fingers having lengths that are between about 0.05 time the distance L and about 0.3 times the distance L, the first plurality of dummy fingers having widths that are between about 0.15 times the distance L and about 0.65 times the distance L, and the first plurality of dummy fingers are spaced from corresponding ones of the second plurality of fingers by gaps having distances between about 0.05 time the distance L and about 0.3 times the distance L.
